(19) United States
(12) Patent Application Publication
(10) Pub. No.: US 2010/0310849 A1
(43) Pub. Date: Dec. 9, 2010

(54) SOLID POWDER FORMULATIONS FOR THE PREPARATION OF RESIN-COATED FOILS AND THEIR USE IN THE MANUFACTURE OF PRINTED CIRCUIT BOARDS

(75) Inventors: Jürgen Kress, Riehen (CH); Stephan Tusl, Mainz (DE); Sandro Cicchetti, Suhr (CH); Thierry Bécret, Blotzheim (FR)

Correspondence Address: EDWARDS ANGELL PALMER & DODGE LLP, P.O. BOX 55874, BOSTON, MA, 02205, US

(73) Assignee: ATOTECH DEUTSCHLAND GMBH, Berlin (DE)

(21) Appl. No.: 12/747,374

(22) PCT Filed: Dec. 10, 2008
(86) PCT No.: PCT/EP08/10473

§ 371 Date: Aug. 23, 2010

(30) Foreign Application Priority Data
Dec. 12, 2007 (EP) 07024111.2

(51) Int. Cl. B32B 15/092; C08L 63/00; C08L 63/04; C08L 61/06; C08K 3/22; C08K 3/18; C08K 3/34; B32B 27/38; B32B 27/12; H05K 1/02

(52) U.S. Cl. 428/220; 525/481; 525/486; 524/541; 525/452; 525/107; 524/430; 524/437; 524/447; 524/451; 428/413; 428/221

(57) ABSTRACT

The invention relates to solid thermosetting resin compositions and resin-coated foils, glass cloth reinforced resin-coated foils using the same and their use in the manufacturing of printed circuit boards.

### FIELD OF INVENTION

The invention relates to a solid powder formulation comprising a solid thermosetting resin composition and a resin-coated foil obtained from such a formulation, optionally reinforced, and their use in the manufacturing of printed circuit boards.

### BACKGROUND ART

For the manufacturing of printed circuit boards (PCB), thermosetting epoxy resin formulations are widely used. Due to their moderate price and good overall technical characteristics they are still the industry standard for most applications in electronics (Martin W. Jawitz (Ed.), Printed circuit board materials handbook, Mc Graw Hill, New York 1997, chapter 6). Important characteristics which make epoxies so versatile raw materials are for example high thermal stability, good copper peel strength, or low water absorption. To ensure the required flame retardancy of the finished electronic product, the epoxy resins are themselves normally formulated to become flame retardant. This can, for example, be effected by the use of brominated epoxy resins. But environmental concerns and requests from OEMs (Original Equipment Manufacturer) increasingly restrict their usage. Therefore other flame retardants based on phosphorus compounds or metal hydroxides (e.g. from Al or Mg) find application.

In order to improve the mechanical properties, reinforcements are often applied in combination with epoxy resins thus to form prepregs and laminates (Martin W. Jawitz (Ed.), Printed circuit board materials handbook, Mc Graw Hill, New York 1997, chapter 9). The reinforcement most currently used are glass fabrics. For example, prepregs are currently manufactured by impregnating glass fabrics in so called treaters in which the fabric is soaked with a solvent based solution of the epoxy resin formulation and subsequent slow evaporation of the solvent and concurrent b-staging of the resin. Owing to the low viscosity of the solution, good wetting of the glass fabric is easily achieved.

Intrinsically, solvent based processes have some serious disadvantages. The solvent itself is not part of the finished product, i.e. it acts only as a carrier medium for the solute (e.g. the epoxy resin formulation). Such a solution typically has a solid content of about 50%. That means that after the solvent served its purpose, it is evaporated which needs a lot of energy and has eventually to be disposed of, normally by incineration, i.e. about 50% of the starting material ends up as waste. This adds substantially to the investment and to the running costs of any such plant. Health, environment, safety concerns, and VOC regulations are other topics of significant concern. In addition, the equipment needed to handle the solvent loaded waste air and the detectors to prevent explosive atmospheres make such a coating line complex and expensive. The rather time consuming processes of releasing the solvents and afterwards re-levelling of the surface are inherently slow and less efficient than just melting and levelling a powder matrix. Furthermore, intermediate and final products are guaranteed to be solvent free when powder coatings are employed, even when fast curing systems are used. In the light of that, a high throughput with relatively compact coating lines can be achieved. On the other hand there are the stringent requirements of base materials used in the printed circuit board industry. Especially ultra thin prepregs or resin coated foils intended for the production of high density interconnect layers (HDI layers) must cope with extensive OEM specifications which are far beyond what is expected from ordinary powder coating applications. Good solder shock resistance which is vital to pass numerous lead free solder reflow cycles requires outstanding thermal robustness. A low water uptake is needed to meet JEDEC (Joint Electron Device Engineering Council) requirements (Reference for JEDEC requirement, numerous lead free solder shock tests, and CAF resistance). A low melt viscosity allows the perfect impregnation of woven glass fibres which is essential for the material to have resistance to conductive anodic filament growth (CAF-resistance). All these properties have to be maintained in the presence of the halogen free flame retardant agent which is required to reach sufficiently low UL-VO burning times.

Most of the used thermosetting resin compositions for the impregnation of glass fabrics and for the coating of substrates used in the PCB industry are diluted in organic solvents as well as the majority of the applied commodities. All applicable halogen free flame retardant agents are either diluted or liquid phosphorus containing components or solid additives without the potential to react into the thermosetting epoxy resin matrix. Another possibility would be the use of metal hydroxides but an unacceptable high loading of such fillers is needed. In general all of these fillers deteriorate mechanical and others properties to a significant degree. High filler loadings also lead to an strong increase of the melt viscosity and thus to a reduced ability of wetting the fibres. Therefore it would be desirable to have an epoxy resin formulation based on 100% solid content which has the capacity to impregnate and wet a glass cloth. That solid resin formulation could be made as a powder and applied as such.

The overall solid resin formulation must meet several boundary conditions. The Tg of the composition in the uncured stage (A-stage) must be high enough so that the various processing steps which are necessary to make a powder (extrusion, milling, classifying, sieving) can be executed. In the case of a Tg too low, agglutination could occur. At the same time the melt viscosity of the composition at elevated temperature must be low enough to allow for the proper impregnation of the glass cloth by the resin. Furthermore, outstanding thermal resistance, UL-VO burning performance without using halogenated components, a low water uptake, and excellent copper adhesion are crucial parameters to fulfil typical requirements for base materials used in PCB applications.

WO 2004/085550 A2 relates to a powder coating, an aqueous dispersion based on the powder coating, a process for its preparation and a process for the preparation of coating layers on substrates, inter alia for the preparation of multilayer structures. The process does not require the use of any organic solvent.

### SUMMARY OF INVENTION

It is the object underlying the present invention to provide a powder coating composition enabling a fast curing at low melt viscosity but still high Tg of the powder (above 50° C.). The composition should be useful in the preparation of flame retardant resin-coated foils wherein the flame retardant should not have a negative impact on the curing mechanism. Further, it is the object of the invention to provide a composition exhibiting a high copper peel strength, improved shelf life and good process characteristics like higher throughput in the milling process. The composition must be capable to successfully impregnate a glass fabric in a subsequent lamination step without the formation of voids, wetting defects, air bubbles and the like.

According to the present invention this object is achieved by a powder formulation comprising a thermosetting resin composition comprising the following components:
(A) an epoxy resin solid at 20° C.,
(B) phenolic hardener solid at 20° C. having an average functionality >3, preferably >5, more preferably >7 and most preferred 9,
(C) a phosphorous-modified epoxy resin solid at 20° C. and
(D) a latent catalyst.

### DESCRIPTION OF INVENTION

Component (A) is preferably a chemically modified epoxy resin having an epoxy equivalent weight (EEW) ranging from 150 to 1800 g/eq.

The term “epoxy equivalent weight (EEW)” is defined as the weight of resin in grams which contains one gram equivalent of epoxy. If the resin chains are assumed to be linear with no side branching and it is further assumed that an epoxy group terminates each end, then the epoxide equivalent is one-half the average molecular weight of a diepoxy resin, one-third the average molecular weight of a triepoxy, etc. In the art the term “epoxy value” is also employed and represents the fractional number of epoxy groups contained in 100 grams of resin. The two terms are convertible. Dividing the epoxy value into 100 gives the epoxide equivalent. Practical methods for determination of epoxide equivalents are based on the addition of a hydrogen halide to the epoxy group. The difference between the amount of acid added and the amount unconsumed, determined by titration with standard base, is a measure of the epoxy content. In practice, hydrogen chloride, hydrogen bromide, or hydrogen iodide is used.

The above chemically modified epoxy resin includes isocyanate modified epoxy resins, butadiene-acrylnitrile rubber-modified epoxy resins, multifunctional epoxy-phenol novolak resins and bisphenol-A based or cyclo-aliphatic epoxy resins.

Suitable solid hardeners (B) for use in the present invention are selected from the group consisting of phenol novolak resins, cresol novolak resins and bisphenol A novolak resins, which do not have any epoxy groups like the hardeners described in WO 2004/085550 A2.

According to a preferred embodiment of the invention, the solid hardener (B) is a phenolic novolak resin having an average functionality of at least 9, wherein average functionality denotes the average number of functional groups (—OH) per molecule. Such solid hardeners include, for example, TD 2131 (available from Dainippon Ink & Chemicals Inc.) and PF 0790 K04 (available from Hexion).

Component (C) is a solid phosphorous-modified epoxy resin selected from, for example, the group consisting of DOPO (Di-hydro-9-oxa-10-phosphaphenantrene-10-oxide)-modified multifunctional epoxy phenol or cresol novolak resins and DOPO-HQ 2-(6-0xo-6H-6,5-dibenzo[c,e][1,2] oxaphosphine-6-yl)benzene-1,4-diol) modified bi-functional epoxy resins. Additionally, Struktol VP 3752 (available from Schill+Seilacher) and EXA 9726 (available from Dainippon Ink & Chemicals Inc.) may be mentioned. EXA 9726 basically corresponds to EXA 9710 which is a solution of EXA 9726 in an organic solvent (MEK, acetone).

Further suitable solid phosphorous-modified epoxy resins for use in the present invention are described in United States patent application publication No. US 2006/0223921 A1. This document discloses a prepolymer for flame resistant polymers which is obtained by reacting at least one phosphinic acid derivative of formula I

(R¹O)(R²)P(O)—R³,

wherein R¹ and R² independently of one another represent an optionally substituted alkyl, aryl, arylalkyl, alkylaryl or alkylarylalkyl group with 1 to 20 carbon atoms,

R³ represents hydrogen or an optionally substituted alkyl, aryl, arylalkyl, alkylaryl or alkylarylalkyl group with 1 to 20 carbon atoms, with, for example, an epoxy resin.

Further suitable phosphorous-modified epoxy resins for use in the present invention are described in Japanese patent application publication No. JP 2000080251.

According to a preferred embodiment of the invention, the solid phosphorous modified epoxy resin is a bifunctional epoxy resin having an EEW less than 500 g/eq and a phosphorous content more than 2% by weight.

Component (D) is a latent catalyst. Said latent catalyst is at ambient temperature chemically blocked and the catalytically active component is generated at elevated temperature >120° C., such as Dyhard® UR 300 and Dyhard® UR 500 (available from Degussa).

The latent catalyst (D) is a substituted urea catalyst or an urone-type catalyst. Such substituted urea catalysts have the general chemical structure

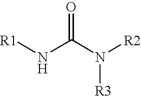

wherein R¹ denotes a substituted or unsubstituted phenyl group and wherein

R² and R³, which may be the same or different, are selected from linear or branched alkyl groups having 1 to 6 carbon atoms.

Quaternisation of such substituted urea catalysts results in urone-type catalysts having the formula [R¹R²N—C(OR³)═NR⁴R⁵]⁺X⁻ (wherein R′ to R⁵ are selected from hydrogen or organic residues and X″ is an acid anion).

A suitable urone-type catalyst for use in the present invention is, for example, URAcc 43 (available from Degussa).

The thermosetting resin composition may optionally further comprise an inorganic filler (E). Such inorganic fillers include SiO₂, Al₂O₃, ALOOH, kaolin and talc.

Preferably, the average particle size of the inorganic filler is less than 5 micron.

While the composition of the powder formulation may vary depending on the desired physical characteristics, it generally comprises components (A) to (D) and, optionally, component (E) in the amounts specified below:

(i) 25-50% by weight and preferably 35-45% by weight of component (A),
(ii) 15-25% by weight of component (B),
(iii) 15-25% by weight of component (C),
(iv) 0.05-1% by weight of component (D),
(v) 0-40% by weight and preferably 20-30% by weight of component (E).

For example, a preferred composition comprises 35 to 45% of an epoxy resin selected from the following: XAC 4151 (available from Asahi Kasei), AER 4151 (available from Asahi Kasei), EPPN 502H (available from Nippon Kayaku), Hypox RK84L (available from CVC) and mixtures thereof. A preferred embodiment of component (A) consists of all of the aforementioned four epoxy resins.

A suitable hardener (B) for use with such epoxy mixtures is PF 0790 K04 (available from Hexion).

According to a preferred embodiment of the invention, EXA 9726 (available from Dainippon Ink & Chemicals Inc.) is used as phosphorous-modified epoxy resin.

Preferably, URAcc 43 (available from Degussa) is used as a latent catalyst with zo the above mixtures.

A particularly preferred powder formulation comprises XAC 4151 (available from Asahi Kasei), AER 4151 (available from Asahi Kasei), EPPN 502H (available from Nippon Kayaku), Hypox RK84L (available from CVC), PF 0790 K04 (available from Hexion), EXA 9726 (available form Dainippon Ink & Chemicals Inc.) and URAcc 43 (available from Degussa) in the amounts (i) to (iv) specified above.

The compositions according to the present invention feature a high latency and a high glass transition temperature after curing.

In the present invention latency is defined as follows:

Latency[° K]=Exothermal Peak Temperature[° C.]−Exothermal Onset Temperature [° C.] as determined by differential scanning calorimetry (DSC).

Thus, a lower value for latency (spread from onset to peak temperature) means a narrower reaction heat peak and therewith a more latent curing mechanism, especially if the onset temperature is above 150° C. and the peak temperature is below 180° C. A wider enthalpy peak means a declined shelf life and no fast cure-ability.

A high glass transition temperature (Tg) after curing is desirable in that application because many of the physical properties deteriorate around the glass transition temperature, e.g. reduced stiffness and increased thermal expansion.

As will be explained below, the compositions according to the present invention achieve the desired high latency and the high Tg after curing by combination of catalyst (D) and hardener (B). In other words, this combination of the hardener and, in particular, a hardener having an average functionality of >3, preferably >5, more preferably >7 and most preferred ≧9 and a latent catalyst and, in particular, a substituted urea or urone-type catalyst performs considerably better than prior art thermosetting epoxy resin compositions.

Preferably, the compositions according to the present invention have a latency, measured as spread from onset temperature to peak temperature, below 20K. Preferably the onset temperature ranges from 140-160° C. and the peak temperature shall be below 180° C.

After curing, the compositions preferably have a Tg ranging from 150-160° C.

Another important feature of the compositions according to the present invention is their improved shelf life and their fast curing ability. Both items are important for the handling and processing of the resin compositions used to prepare resin-coated foils. In the compositions according to the present invention there is no relevant curing below 120° C., but rather fast curing occurs at elevated temperatures above 150° C. At a temperature of 160° C., the formulations can be fully cured within 30 minutes and at 170° C. only 15 minutes baking time is sufficient for full cure.

The shelf life of the compositions according to the present invention is demonstrated by their loss in reaction enthalpy which is less than 15%. It does not lead to significant changes in melt viscosity and slow characteristics. If the compositions according to the present inventions are stored at temperatures less than 6° C., no changes in reaction heat were observed.

In view of their improved shelf life, it is possible to store the powder formulation according to the present invention for more than six months.

The compositions according to the present invention also exhibit an improved flame retardancy as far as the amount of flame retardants and their effects on the curing mechanism are concerned. Thus, the flame retardant has a chemical structure similar to the epoxy resin used as component (A) in the compositions according to the present invention, except for comprising phosphorous as an additional element. Therefore, it is incorporated into the backbone structure obtained by curing the thermosetting resin composition, which incorporation results in a lower concentration of flame retardant to achieve VO ratings when compared to the use of conventional flame retardants known in the prior art. In addition, in view of its structural similarity, the flame retardant does not adversely affect the curing mechanism by which the compositions are thermoset, since the flame retardant becomes part of the crosslinked product.

A particularly preferred solid phosphorous-modified epoxy resin for use in the present invention is the polyaddition product of 2-(6-0xo-6H-6,5-dibenzo[c,e][1,2] oxaphosphine-6-yl)benzene-1,4-diol) with (the product of etherification of phenol/formaldehyde polycondensation and 1-chloro-2,3-epoxypropane). The structure of such DOPO modified multifunctional epoxy phenol novolak resins is shown below:

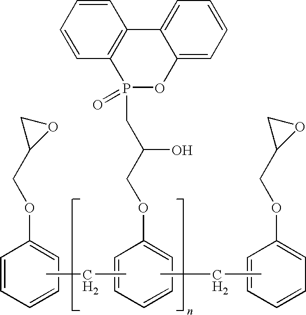

Other particularly preferred solid phosphorous-modified epoxy resins for use in the present invention are HCA-HQ modified difunctional bisphenol A epoxy resins as shown below:

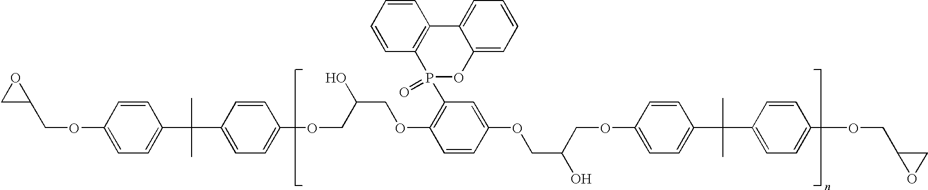

The preparation of the above mentioned epoxy resins is described in Japanese patent application publication No. JP 2000080251 and United States patent application publication No. US 2006/0223921 A1.

The solid phosphorous-modified epoxy resin reduces the total burning time of the samples tested significantly. At the same time, the samples exhibited an excellent copper peel strength when compared to samples comprising a conventional phosphorous flame retardant agent.

In summary, the compositions according to the present invention have improved physical properties qualifying them for their use for the preparation of resin coated foils which, in their turn, can be used in the manufacture of printed circuit boards. In particular, the powder formulations comprising the thermosetting resin composition as described hereinbefore have the following physical properties:
(i) a glass transition temperature in the non-converted A-stage greater than 50° C. as determined by DSC according to IPM 650 2.4.25 C,
(ii) a melt viscosity of less than 20 Pas at 140° C., measured by using a cone plate configuration with an angle of 2° and a rotation speed of 5 rpm,
(iii) a glass transition temperature of >150° C. after curing at 190° C. for 20 minutes as determined by DSC according to IPM 650 2.4.25 C,
(iv) a decomposition temperature greater than 390° C. at 1% weight loss determined by thermogravimetric analysis (TGA) and
(v) a dielectric constant (Dk) of <3.4 and a dissipation factor (Df) of <0.018 determined according to ASTM D 150-98 (2004) and measured at 1 GHz.

The above mentioned thermogravimetric analysis (TGA) is a method known in the art which can be used to determine the weight change of a sample depending on its temperature so that TGA is a tool allowing to analyse the thermal decomposition behaviour or profile of materials.

The present invention further provides a resin-coated foil obtainable by coating a substrate with the powder formulation as described hereinabove to obtain a coated substrate and thermally fixing the powder formulation at elevated temperatures, such as 150° C. and above, to the substrate to obtain a resin-coated foil.

Suitable substrates for use in such a coating process are selected from metal foils e.g. copper, aluminium or nickel as well as polymeric foils withstanding elevated temperature exposure at the desired level to melt the described thermosetting resin composition.

Preferably, the resin-coated foil comprises reinforcements, preferably those used to form prepregs or laminates. Such reinforcements include fabric cloth and glass cloth.

Thus, the present invention further provides a resin-coated foil which is reinforced with E-glass cloth, for example, and clad with a metal such as electrodeposited copper.

Such a reinforced resin-coated foil resists delamination for more than 30 minutes when subjected to the delamination test according to IPC TM 650 2.4.24.1.

In addition, it shows a copper peel strength of greater than 17 N/cm at a 35 mlcron copper thickness in the test according to IPC TM 650 2.4.8 C.

After removal of the copper cladding, such a laminate construction as described above resists the solder dip test at 288° C. for 20 seconds after boiling it in a high pressure cooker vessel for 30 minutes at 2.6 bar (which corresponds to 140° C.) such that low delamination or blistering is observed in the test according to IPC TM 650 2.6.16. The 40 micron thick film shows a water uptake of less than 1% in the test according to IPC TM 650 2.6.2 C.

When tested in the vertical UL-burning test, the glass cloth reinforced film gets a VO rating either pressed on a 200 micron thick FR4 core up to a supplementary thickness of 240 micron (corresponds to 6 plies) respectively pressed as bare laminate to a thickness of 160 micron (corresponds to 4 plies) in the absence of halogenated components.

Compounding of claimed thermosetting resin composition can be done by an extruder whereas the gently incorporation of the catalyst C is a vital parameter to maintain the said latency. A chill belt and cooled rollers shall cool reduce the temperature of the melt so that it can eventually be crushed into flakes.

The powder is made from the said flakes by milling e.g. with an impact mill or air jet mill. If required by the subsequent coating processes a classifier can be used to remove the fines from the powder. The average particle size can thus be adjusted to the desired value.

The powder can be applied on a substrate e.g. metal foil as mentioned above to be thermally fixed at elevated temperature to the substrate.

### BRIEF DESCRIPTION OF THE DRAWINGS

FIG. 1 shows a DSC scan of a powder formulation according to the present invention and a comparative formulation.

FIG. 2 shows the curing speed expressed in % conversion of the compositions according to the present invention at various temperatures.

The invention is further illustrated by the following examples. In these examples, the majority of the performed test methods are related to the IPC TM650 (Association Connecting Electronic Industries). This manual establishes uniform methods for testing electronic and electrical parts including basic environmental, physical and electrical tests. These tests were developed to support IPC standards and specifications (IPC TM650 (Association Connecting Electronic Industries) 2215 Sanders Road, Northbrook, Ill. 60062-6135).

More particularly, the parameters mentioned below were tested as follows:
(a) The glass transition temperature (Tg) after curing was determined according to IPC TM 650 2.4.25 C.
(b) The gel time was determined according to IPC TM 650 2.3.18 A.
(c) The time to delamination (TMA method) was determined according to IPC TM 650 2.4.24.1.
(d) Viscosity was measured by using a cone plate configuration with an angle of 2° and a rotation speed of 5 rpm. The temperature was set to 140° C. (+/−0.5K).
(e) HPCT was determined according to test method IPC TM 650 2.6.16.
(f) The peel strength was determined according to IPC TM 650 2.4.9.
(g) The total burning time (per sample) was determined according to IPC TM 650 UL.
(h) The water uptake was determined according to IPC TM 650 2.6.2.1.

### Example 1

The following components were used to prepare thermosetting resin compositions:

Hardener A: Phenol novolak resin average functionality >9 (component B)

Hardener B: Phenol novolak resin average functionality <3

Catalyst 1: Imidazole derivative (e.g. 2-Phenylimidazole Curezol 2-PZ available from Shikoku Co. Ltd.)

Catalyst 2: substituted urea catalyst (component D)

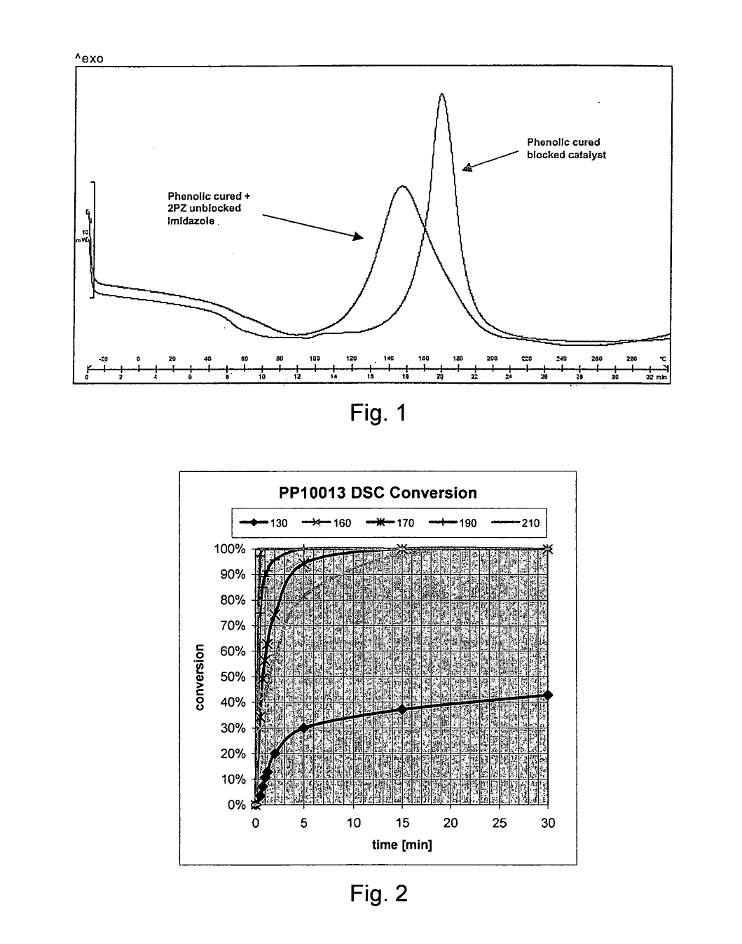

The formulations shown in table 1 were mixed at elevated temperature and then investigated by differential scanning calorimetry (DSC) in the temperature range from −30° C. to 300° C. in order to detect the reaction enthalpy and glass transition temperature after curing. A typical DSC scan is shown in FIG. 1.

TABLE 1

| | | | | Tg | Peak | | Peak | | |
|---|---|---|---|---|---|---|---|---|---|
| | | | Tg (Powder) | (Cured) | Temp | Latency | Energy | Geltime | T288 |
| Formulation | Catalyst | Hardener | [° C.] | [° C.]* | [° C.] | [K] | [J/g] | [sec]** | [min]*** |
| ST00034-1 | 1 | A | 70 | 163 | 147 | 27 | 124 | 25 | >30 |
| ST00034-2 | 2 | A | 60 | 157 | 170 | 14 | 134 | 66 | >30 |
| ST00034-3 | 1 | B | 64 | 150 | 148 | 36 | 112 | 30 | >30 |
| ST00034-4 | 2 | B | 50 | 145 | 167 | 21 | 133 | 78 | >30 |

*Tg after Curing by DSC → IPC TM 650 2.4.25C
**Geltime → IPC TM 650 2.3.18A
***Time to Delamination (TMA Method) → IPC TM 650 2.4.24.1

The said isocyanate modified epoxy resin made the backbone for this investigation. The hardener amounts were set to the stoichiometrical ratio. The catalyst level was 0.8% by weight for all formulations.
ST00034-1

| Component | Amount [g] | Equivalent |
|---|---|---|
| XAC 4151 | 10.00 | 78.7% |
| PF0790 K04 | 2.60 | 20.5% |
| 2PZ | 0.10 | 0.8% |

ST00034-2

| Component | Amount [g] | Equivalent |
|---|---|---|
| XAC 4151 | 10.00 | 78.7% |
| PF0790 K04 | 2.60 | 20.5% |
| URAcc 43 | 0.10 | 0.8% |

ST00034-3

| Component | Amount [g] | Equivalent |
|---|---|---|
| XAC 4151 | 10.00 | 79.4% |
| TD2131 | 2.50 | 19.8% |
| 2PZ | 0.10 | 0.8% |

ST00034-4

| Component | Amount [g] | Equivalent |
|---|---|---|
| XAC 4151 | 10.00 | 79.4% |
| TD2131 | 2.50 | 19.8% |
| URAcc 43 | 0.10 | 0.8% |

The values in Table 1 proof that just the correct combination of catalyst and curing agent performs well in both the desired low latency and the high Tg after curing. The combination of a high functionality of the hardener and a urone-type catalyst (formulation ST00034-2) is performing considerably better than the other comparative examples (formulations ST00034-1, ST00034-3 and ST00034-4).

### Example 2

The shelf life and the curing ability of the formulations described below were tested as follows:

The loss in reaction enthalpy was used to verify the shelf life of the fully formulated powder. Straight after manufacturing the reaction enthalpy was determined and taken as reference. Then the powder was stored at ambient ternperature <23° C. to be tested after three and six months again. The curing conditions were tested via DSC. The specimens were exposed to varying temperatures and times inside the DSC measuring cell. After exposure the remaining reaction enthalpy was detected and taken as degree of conversion.

As shown in FIG. 2 there is no relevant curing below 120° C. but rather fast curing speed at elevated temperatures above 150° C. At a temperature of 160° C. the formulation can be fully cured within 30 minutes, at 170° C. only 15 minutes baking time is sufficient for full cure.

In Table 2 the loss in reaction enthalpy is shown in order to demonstrate the shelf life of several formulations (different epoxy resin combinations) all cured with the claimed combination of phenolic hardener and blocked catalyst. Typically a reduction of reaction enthalpy below 15% is tolerable and does not lead to significant changes in melt viscosity and flow characteristics. If the formulation is stored at temperatures ≦6° C. no changes in reaction heat were observed.

TABLE 2

Exothermal Peak
Energy J/g

| Formulation # | initial | after storage | Loss % |
|---|---|---|---|
| ST00036* | 125 | 110 | 12% |
| ST00036** | 120 | 110 | 8% |

*powder stored at ambient temperature for >6 months
**powder stored at ambient temperature for >3 months

### Formulation Details

ST00036: comprising said isocynate modified epoxy resins, phenol novolak hardener (B), inorganic filler (E) and substituted urea catalyst (D)

| | parts by | |
|---|---|---|
| Component | weight | wt % |
| XAC 4151 | 200.00 | 32.00 |
| AER 4152 | 200.00 | 32.00 |
| Silbond* | 100.00 | 16.00 |
| PF0790K04 | 116.00 | 18.56 |
| Epon 1031** | 6.00 | 0.96 |
| URAcc43 | 3.00 | 0.48 |
| Total | 625.00 | 100.00 |

*Silbond is a SiO₂ filler available from Quarzwerke
**Epon 1031 is a solid multifunctional epichlorohydrine/tetraphenylol ethane epoxy resin available from Hexion (in parts UV blocking)

### Example 3

Formulation ST00036 described in Example 2 was used as reference and the below mentioned phosphor sources were added in a ratio desired to have a total phosphor content of 1% by weight.

The phosphorous content, the melting point and the chemical structure of the flame retardants used is shown in Table 3 below.

The list contains only potential phosphorus sources which are by their nature applicable in powder formulations, e.g. having a melting point >50° C.

TABLE 3

| | Phos- | Melt- | |
|---|---|---|---|
| | phorus | ing | |
| Component No. | content | Point | Chemical structure |
| 1) Sanko HCA (DOPO) Di-hydro- 9-oxa-10- phospphaphenantrene- 10-oxide | 14% | 118° C. | 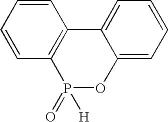 |
| 2) Sanko HCA-HQ (DOPO-derivate) Di-hydro-9-oxa-10- phosphaphenantrene- 10-oxide-benzendiol | 9.5% | 250° C. | 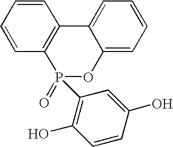 |
| 3) Dow XZ 92588 | n.a. | 86° C. | Phosphorus containing |
| | | | phenolic co-hardener |
| 4) Component C | >2% | 89° C. | Phosphor modified di- |
| | | | functional epoxy resin |
| | | | (EXA 9726) |
| 5) Polydis Struktol | 8% | 70° C. | DOPO modified polyester |
| 3780 | | | resin |

All tested phosphorus sources were efficient and reduced the total burning time significantly. The best overall performance was reached with component C. The free DOPO containing formulation performed very poor concerning T288 resistance and copper peel strength. The DOPO derivate HCA-HQ was much better but remaining (non converted) particles were observed. This is most likely due to the high melting point of the component. Also the component XZ 92588 reduced the copper peel strength considerably. See results table 4. The reference ST00036 does not contain any flame retardant.

TABLE 4

| | | | | | | | | IPC TM- |
|---|---|---|---|---|---|---|---|---|
| | | | | | | | | 650-Test |
| Formulation | ST00036 | ST00037 | ST00040 | ST00047 | ST00053 | ST00066 | Unit | Method |
| Content | | | | | | | | |
| Component No. | Reference | 3) | 1) | 2) | 5) | 4) | | |
| Thermal Powder | | | | | | | | |
| Tg before curing (DSC DIN | 53 | 54 | 44 | 49 | 50/73 | 52 | ° C. | |
| Mid Point) | | | | | | | | |
| Tg after curing (DSC Din Mid | 156 | 136 | 135 | 154 | 128 | 150 | ° C. | |
| Point) | | | | | | | | |
| Exothermal Peak Temperature | 176 | 179 | 178 | 174 | 177 | 176 | ° C. | |
| Exothermal Peak Energy | 125 | 96 | 141 | 118 | 104 | 140 | J/g | |
| Geltime @ 180° C. [s] | 89 | 174 | 152 | 91 | 120 | 77 | | |
| Mechanical Powder Powder | | | | | | | | |
| Rhenology Min viscosity Pas | 16 | 31 | 8 | 29 | 39 | 18 | Pas | |
| Thermal R-RCF* | | | | | | | | |
| Time to delamination T288 | >30 | >30 | 3.7 | >30 | >30 | >30 | min_° C. | 2.4.24.1 |
| (sandwich) Reference | | | | | | | | |
| Time to delamination T288 | >30 | >30 | 2.6 | >30 | >30 | >30 | min_° C. | 2.4.24.1 |
| (sandwich) after 24 h @ 50% | | | | | | | | |
| rel. H + 23° C. | | | | | | | | |
| High Pressure cocker-test | pass | pass | pass | pass | pass | pass | pass/fail | 2.6.16 |
| Mechanical R-RCF* | | | | | | | | |
| Peel strength (with 35 μm Cu) | 18.3 | 13.6 | 10.7 | 18.6 | 16 | 17.3 | N/cm | 2.4.9 |
| Chemical R-RCF* | | | | | | | | |
| Total burning time (per | 6.2 | 4.2 | 4.4 | 4.6 | 4.8 | 4.2 | sec | UL |
| sample) | | | | | | | | |
| H2O uptake | 0.9 | 0.8 | 0.9 | 1 | 1.1 | 0.8 | % | 2.6.2.1 |

*specimen pressed as glass cloth reinforced resin coated copper foil (R-RCF)

In summary, the present invention provides a powder coating composition comprising epoxy resins, solid hardeners, a phosphorous-containing difunctional flame retardant which has a structure similar to the aforementioned epoxy resins, a latent catalyst, particularly an urea catalyst and optionally an inorganic filler. The combination of such hardeners and catalysts enables a fast curing at low melt viscosity but still high Tg of the powder (above 50° C.). The phosphorous-containing flame retardant becomes part of the resin backbone. It can be used in small amounts compared to hitherto used flame retardants and does not have a negative impact on the curing mechanism.

The composition according to the present invention exhibits a higher copper peel strength, improved shelf life and good process characteristics like higher throughput in the milling process.

1. A powder formulation comprising a thermosetting resin composition comprising the following components:
(A) an epoxy resin solid at 20° C.,
(B) a phenolic hardener solid at 20° C. having an average functionality >3,
(C) a phosphorous-modified epoxy resin solid at 20° C. and
(D) a latent catalyst.

2. The powder formulation according to claim 1 wherein said epoxy resin (A) is a chemically modified epoxy resin having an epoxy equivalent weight ranging from 150 to 1800 g/eq.

3. The powder formulation according to claim 1 wherein said solid phenolic hardener (B) is a phenolic novolak resin having an average functionality of at least 9.

4. The powder formulation according to claim 1 wherein said solid phosphorous-modified epoxy resin (C) is a bifunctional epoxy resin having an epoxy equivalent weight less than 500 g/eq and a phosphorous content greater than 2% by weight.

5. The powder formulation according to claim 1 wherein the latent catalyst (D) is a substituted urea or urone-type catalyst.

6. The powder formulation according to claim 1 further comprising an inorganic filler (E).

7. The powder formulation according to claim 6 wherein said inorganic filler (E) has an average particle size less than 5 micron.

8. The powder formulation according to claim 1 consisting essentially of
(i) 25-50% by weight of component (A),
(ii) 15-25% by weight of component (B),
(iii) 15-25% by weight of component (C),
(iv) 0.05-1% by weight of component (D),
(v) 0-40% by weight of component (E).

9. The powder formulation according to claim 8 consisting essentially of
(i) 35-45% by weight of component (A),
(ii) 15-25% by weight of component (B),
(iii) 15-25% by weight of component (C),
(iv) 0.05-1% by weight of component (D),
(v) 20-30% by weight of component (E).

10. The powder formulation according to claim 1 wherein said epoxy resin (A) is selected from the group consisting of isocyanatemodified epoxy resins, butadiene-acrylnitrile rubber-modified epoxy resin, multifunctional epoxy-phenol novolak resin and bisphenol-A based or cyclo-aliphatic epoxy resins.

11. The powder formulation according to claim 1 wherein said solid phenolic hardener (B) is selected from the group consisting of phenol novolak resins, cresol novolak resins and bisphenol A novolak resins.

12. The powder formulation according to claim 1 wherein said solid phosphorous modified epoxy resin is the polyaddition product of 2-(6-Oxo-6H-6,5-dibenzo[c,e][1,2] oxaphosphine-6-yl)benzene-1,4-diol) with (the product of etherification of phenol/formaldehyde polycondensation and 1-chloro-2,3-epoxypropane).

13. The powder formulation according to claim 1 wherein said latent catalyst is selected from the group of having the general chemical structure 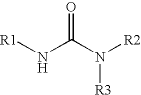
wHerein R1 denotes a substituted or unsubstituted phenyl group and wherein R2 and R3, which may be the same or different, are selected from linear or branched alkyl groups having 1 to 6 carbon atoms.

14. The powder formulation according to claim 1 wherein said filler is selected from the group consisting of SiO₂, Al₂O₃, AlOOH, kaolin and talc.

15. The powder formulation of claim 1 having
(i) a glass transition temperature in the non-converted A-stage greater than 50° C. as determined by DSC according to IPM 650 2.4.25 C,
(ii) a melt viscosity of less than 20 Pas at 140° C., measured by using a cone plate configuration with an angle of 2° and a rotation speed of 5 rpm,
(iii) a glass transition temperature of 150° C. after curing at 190° C. for 20 minutes as determined by DSC according to IPM 650 2.4.25 C,
(iv) a decomposition temperature greater than 390° C. at 1% weight loss determined by thermogravimetric analysis (TGA) and
(v) a dielectric constant (Dk) of <3.4 and a dissipation factor (Df) of <0.018, determined according to ASTM D 150-98 (2004) and measured at 1 GHz.

16. A resin-coated foil obtainable by coating a substrate with the powder formulation according to claim 1 to obtain a coated substrate and thermally fixing the powder formulation at elevated temperature of 150° C. and above to the substrate to obtain a resin-coated foil.

17. The resin-coated foil according to claim 16 comprising reinforcements to form prepregs or laminates.

18. The resin-coated foil according to claim 17 wherein said reinforcements are selected from the group consisting of fabric cloth and glass cloth.

19. The resin-coated foil according to claim 18 which is reinforced with E-glass cloth and clad with electrodeposited copper.

20. The resin-coated foil according to claim 19 having a copper peel strength of more than 17 N/cm at 35 micron copper thickness and resisting delamination at 300° C. for more than 30 minutes.

21. The resin-coated foil according to claim 20 resisting the solder dip test at 288° C. for 20 seconds after removal of the copper cladding and boiling it in an autoclave for 30 minutes.

22. The resin-coated foil according to claim 21 which is free from halogenated compounds and passes the vertical UL-burning test as VO either pressed on a 200 micron thick FR4 core up to a supplementary thickness of 240 micron corresponding to 6 plies, respectively, pressed as bare laminate to a thickness of 160 micron corresponding to 4 plies.

23. A process for the preparation of the powder formulation according to claim 1 comprising the following steps:
(i) mixing components (A) to (D) and optionally component (E),
(ii) meltextruding the mixture obtained in step (i) and
(iii) milling and sieving the extruded mixture.

24. Use of the resin-coated foil according to claim 16 in the manufacture of printed circuit boards.
